(19) United States
(12) Patent Application Publication
(10) Pub. No.: US 2024/0095418 A1
(43) Pub. Date: Mar. 21, 2024

(54) SYSTEM AND METHOD FOR AN AUGMENTED-VIRTUAL REALITY DRIVING SIMULATOR USING A VEHICLE

(71) Applicant: GM GLOBAL TECHNOLOGY OPERATIONS LLC, Detroit, MI (US)

(72) Inventors: Duncan Lopatine, Athens, GA (US); Russell A. Patenaude, Macomb Township, MI (US)

(73) Assignee: GM GLOBAL TECHNOLOGY OPERATIONS LLC, Detroit, MI (US)

(21) Appl. No.: 17/945,582

(22) Filed: Sep. 15, 2022

(51) Int. Cl. G06F 30/20; A63F 13/245; A63F 13/803; B60W 50/16; G02B 27/01; G09B 9/042; G09B 9/05

(52) U.S. Cl. CPC G06F 30/20; A63F 13/245; A63F 13/803; B60W 50/16; G02B 27/0176; G09B 9/042; G09B 9/05; B60W 2050/146

(57) ABSTRACT

A system for an augmented-virtual reality simulator using a vehicle is provided. The system includes the vehicle including a control feature configured for selective use in an actual operation mode and in a simulation mode. In the actual operation mode, the control feature is utilized to control actual operation of the vehicle. In the simulation mode, the control feature is utilized as an input device to the augmented-virtual reality simulator. The system further includes a computerized simulation controller. The controller includes programming to monitor activation of the augmented-virtual reality simulator, command activation of the simulation mode based upon the activation of the simulator, monitor inputs to the control feature, and operate the simulator based upon the inputs to the control feature. The system further includes a headset configured for being worn by a user providing a graphical rendering to the user based upon the simulator.

### INTRODUCTION

The disclosure generally relates to a system and method for an augmented-virtual reality driving simulator using a vehicle.

A virtual reality simulation may include a headset wearable by a user, wherein the headset includes a display screen. A virtual reality simulation replaces the view of the actual surroundings of the user. A user standing in his or her living room may see through the headset a view of a beach or a view skydiving from a plane. An alternate, virtual reality is graphically presented to the user through the headset.

An augmented reality mixes objects and features from the actual surroundings of the user with virtual renderings upon a headset. A camera upon the headset captures images of the actual surroundings of the user, and computerized programming is used to render an object, features, or a character in the context of the actual surroundings. For example, an empty chair may actually be in front of the user wearing a headset. Computerized programming may render an animated fictional character, with the graphics being configured for making the fictional character appear to be sitting on the actual chair.

The headset may include programming to track movement of the user's head and change a viewpoint or perspective of graphics illustrated to the user based upon the movement. As the user turns his or her head to the left, the graphics rendered upon the headset pan to the left in coordination with the actual movement of the head. Additionally, a camera upon the headset and/or a camera in a surrounding environment of the user may capture movement of the user. Virtual hands may be graphically rendered in the view provided by the headset, with movement of the virtual hands mimicking the actual movement of the user's hands. Actual movement of the user's hands may be utilized as a control input to simulation programming, for example, with virtual movement of the user's hands being used to simulate and provide a judged score for a dance routine.

A vehicle includes a plurality of control devices or input devices. A steering wheel is used to provide left-right directional control of a vehicle. An accelerator pedal enables a user to maintain or increase a speed of the vehicle. A brake pedal enables a user to slow or stop the vehicle. A transmission gear selector enables a user to select a driving mode of the vehicle (park, reverse, neutral, drive, etc.)

### SUMMARY

A system for an augmented-virtual reality simulator using a vehicle is provided. The system includes the vehicle including a control feature configured for selective use in an actual operation mode and in a simulation mode. In the actual operation mode, the control feature is utilized to control actual operation of the vehicle. In the simulation mode, the control feature is utilized as an input device to the augmented-virtual reality simulator. The system further includes a computerized simulation controller. The controller includes programming to monitor activation of the augmented-virtual reality simulator, command activation of the simulation mode based upon the activation of the augmented-virtual reality simulator, monitor inputs to the control feature, and operate the augmented-virtual reality simulator based upon the inputs to the control feature. The system further includes a headset configured for being worn by a user providing a graphical rendering to the user based upon the augmented-virtual reality simulator.

In some embodiments, the control feature includes one of a steering wheel, an accelerator pedal, a brake pedal, or a transmission gear selector.

In some embodiments, the vehicle includes a plurality of control features configured for selective use in an actual operation mode and in a simulation mode. In the actual operation mode, the control features are utilized to control actual operation of the vehicle. In the simulation mode, the control features are utilized as input devices to the augmented-virtual reality simulator. The plurality of control features include a steering wheel, an accelerator pedal, a brake pedal, and a transmission gear selector.

In some embodiments, the computerized simulation controller further includes programming to monitor a transmission mode of the vehicle and enable activation of the augmented-virtual reality simulator based upon the transmission mode indicating that the vehicle is in park.

In some embodiments, the augmented-virtual reality simulator includes virtual reality. The graphical rendering replaces visible features in an environment of the user.

In some embodiments, the augmented-virtual reality simulator includes augmented reality, wherein the graphical rendering includes a mixture of images of visible features in an operating environment of the user and computerized graphics rendered based upon a three-dimensional model.

In some embodiments, the augmented-virtual reality simulator includes a driving simulation.

In some embodiments, the driving simulation includes a race.

In some embodiments, the driving simulation includes a virtual test drive.

In some embodiments, the driving simulation includes driving instruction for a student driver.

In some embodiments, the augmented-virtual reality simulator includes a simulation of operating a boat or an airplane.

In some embodiments, the augmented-virtual reality simulator includes operation of one of vibration outputs, haptic outputs, climate control system outputs, or audio outputs.

In some embodiments, the augmented-virtual reality simulator includes limited-edition non-fungible tokens.

According to one alternative embodiment, a system for an augmented-virtual reality simulator using a vehicle is provided. The system includes the vehicle including a control feature configured for selective use in an actual operation mode and in a simulation mode. In the actual operation mode, the control feature is utilized to control actual operation of the vehicle. In the simulation mode, the control feature is utilized as an input device to the augmented-virtual reality simulator. The system further includes a computerized simulation controller. The controller includes programming to monitor activation of the augmented-virtual reality simulator, command activation of the simulation mode based upon the activation of the augmented-virtual reality simulator, monitor inputs to the control feature, and operate the augmented-virtual reality simulator including a driving simulator configured to simulate a virtual test drive based upon the inputs to the control feature. The system further includes a headset configured for being worn by a user providing a graphical rendering to the user based upon the augmented-virtual reality simulator. The augmented-virtual reality simulator enables the user to select from a plurality of virtual vehicles.

In some embodiments, the augmented-virtual reality simulator enables the user to select from a plurality of maps upon which to operate the virtual test drive.

In some embodiments, the augmented-virtual reality simulator identifies a bumpy road condition and controls a vibration unit in a seat of the user based upon the bumpy road condition.

According to one alternative embodiment, a method for an augmented-virtual reality simulator using a vehicle is provided. The system includes operating the vehicle including a control feature configured for selective use in an actual operation mode and in a simulation mode. In the actual operation mode, the control feature is utilized to control actual operation of the vehicle. In the simulation mode, the control feature is utilized as an input device to the augmented-virtual reality simulator. The method further includes, within a computerized processor, monitoring activation of the augmented-virtual reality simulator, commanding activation of the simulation mode based upon the activation of the augmented-virtual reality simulator, monitoring inputs to the control feature, and operating the augmented-virtual reality simulator based upon the inputs to the control feature. The method further includes, within a headset configured for being worn by a user, providing a graphical rendering to the user based upon the augmented-virtual reality simulator.

In some embodiments, monitoring inputs to the control feature includes monitoring inputs to a steering wheel.

In some embodiments, the method further includes, within the computerized processor, monitoring a transmission mode of the vehicle and enabling activation of the augmented-virtual reality simulator based upon the transmission mode indicating that the vehicle is in park.

The above features and advantages and other features and advantages of the present disclosure are readily apparent from the following detailed description of the best modes for carrying out the disclosure when taken in connection with the accompanying drawings.

### BRIEF DESCRIPTION OF THE DRAWINGS

FIG. 1 schematically illustrates a vehicle configured for operating a computerized augmented-virtual reality driving simulator, in accordance with the present disclosure;

FIG. 2 schematically illustrates an interior of the vehicle of FIG. 1, in accordance with the present disclosure;

FIG. 3 illustrates a graphical rendering of a simulation operated by the computerized simulation controller of FIG. 1 within the headset of FIG. 1, in accordance with the present disclosure;

FIG. 4 schematically illustrates the computerized simulation controller of FIG. 1, in accordance with the present disclosure;

FIG. 5 is a flowchart illustrating a method to operate a simulation in the vehicle of FIG. 1, in accordance with the present disclosure; and

FIG. 6 is a flowchart illustrating a method for managing features of a simulation operated in the vehicle of FIG. 1, in accordance with the present disclosure.

### DETAILED DESCRIPTION

A simulation or a computerized simulation is a computerized program configured for providing a computerized approximation of a real-world experience. For example, a vehicle simulator may provide a user with an ability to utilize an electronic steering wheel attached to a desk to provide inputs to the vehicle simulator, and an output display such as a liquid crystal display monitor may provide a rendered street surface. A user may turn the electronic steering wheel to control the output upon the monitor. The computerized simulation may apply rules and context to the approximation, for example, providing graphical images of trees and lampposts to avoid.

A system and method for an augmented-virtual reality driving simulator using a vehicle is provided. The system and method may be described as an augmented-virtual reality simulator or as a computerized simulation useful to render either augmented reality graphics or virtual reality graphics. A headset configured for displaying augmented reality and/or virtual reality graphics to a user sitting in a driver's seat of the vehicle may be utilized. The actual vehicle may be confirmed to be in park when the simulation is initiated. The controls of the vehicle may be disengaged from their normal functions, such that the user may utilize the steering wheel, the pedals, the transmission gear selector, and other control features of the actual vehicle as control inputs to the simulation. A graphical representation of the steering wheel may be provided to the user, and as the user actually turns the steering wheel of the vehicle, the graphical representation of the steering wheel may be controlled to appear to turn. Additionally, hand movements of the user may be monitored to interact with virtual controls. For example, virtual police sirens may be presented for the user to activate by touching a representation of a button. No physical feature or control may be where the user's hand actually goes to activate the virtual button, but the act of moving the hand to the actual location corresponding to the virtual button may be utilized to activate sirens in the simulation.

The simulation may be a racing simulation. The user may be able to compete against time or against virtual computerized racers on a track or on virtual city streets. The vehicle may be configured for wireless communication with a remote server device or directly with another vehicle in vehicle-to-vehicle communications. Users in two separate vehicles may virtually compete with each other, with the computerized programs of each vehicle coordinating with each other regarding location, trajectory, engine speed, etc. of the vehicles. In one embodiment, a remote server device may operate leagues, competitions, services to match racers with similar records, and updating content such as virtual races corresponding with actual races being held in real life.

The simulation may be a sales tool, useful for a car dealership to enable potential customers to virtually test drive vehicles that are currently for sale. For example, a user that currently owns a five year old gasoline powered vehicle manufactured by company A may utilize a simulation published by company B to test drive a new electric vehicle. The user may see graphical renderings of the interior surfaces of the vehicle. The user may virtually drive the vehicle, experience the acceleration of the virtual vehicle, hear sounds from the virtual vehicle played over the sound system of the actual vehicle, and experience other features and options provided by the new vehicle.

The simulation may be a training tool, with a student driver getting time virtually training in the family vehicle prior to actually driving the vehicle upon a roadway.

The simulation may be of a vehicle of a different type from the actual vehicle utilized in the simulation. For example, the simulation may provide a virtual boating experience, with the transmission gear selector of the actual vehicle being utilized to simulate a throttle control in the boat. An electronic seat may be utilized to rock and sway the user to simulate wave action upon the boat. In another example, an airplane simulation may be operated, with a telescoping steering wheel being utilized to simulate a steering wheel/control stick in the simulated plane. As the user pushes the actual steering wheel forward, the simulated plane may be pushed forward into a dive. As the user pulls back on the actual steering wheel, the simulated plane may be shown to climb. The brake pedal and the accelerator pedal may be utilized to simulate left and right rudder controls, respectively, for the virtual airplane.

As electric vehicles charge at a charging station, the user of the vehicle may have to wait in a stationary vehicle for thirty minutes or more as the vehicle charges. The disclosed system and method may be utilized to entertain users and increase user satisfaction while the vehicle is being charged. A company owning a brand of charging stations may offer a program that may be operated locally while at a location operated by the company to build customer loyalty. A company may reward users with non-fungible token (NFT) rewards for buying a vehicle during a promotion, for example, enabling the user to operate a virtual limited-edition Corvette® in simulations or granting a virtual leather wrapped wheel with an insignia to be utilized by the driver in simulations as a reward. NFT rewards may be owned by a specific person utilizing blockchain methods.

Operation of the simulation may include a variety of feedbacks to the user. For example, vibrating mechanisms in the base and back of the user's seat may be useful to provide haptic feedback to the user. Force feedback may be operated through the steering wheel, with servo motors being used to make the steering wheel vibrate or pulse in a direction. Sounds of an engine revving or of a seagull flying by may be played over the sound system of the vehicle. The climate control system of the vehicle may be utilized to provide a puff of air during virtual rapid acceleration or a flow of hot air as virtual sunlight is visible shining upon the user. Voice and/or textual information may be provided contextually, for example, with a virtual salesperson being rendered sitting in the seat next to the user answering questions about the virtual vehicle being test driven or with current sales incentives being scrolled across a view of the user as the simulation is operated.

The disclosed simulations may be operated as virtual reality simulations, with the view of the user being based upon a programmed environment separate from the user's actual environment. In the alternative, augmented reality may be utilized in actual vehicle, for example, with a parked and immobilized vehicle at a shopping center or sporting event enabling users to experience virtually driving the vehicle. The user may see images captured by the headset of the actual control surfaces and the hands of the user upon the control surfaces, with augmented reality being utilized to simulate the vehicle driving down the road or over a forest trail.

The disclosed system and method may include receiving a plurality of control inputs from a variety of actual vehicle controls disconnected from their nominal vehicular functions. The disclosed system and method may include receiving a single control input from a single actual vehicle control, such as the steering wheel or the accelerator pedal. Additional virtual controls may be provided to the user in the simulation, for example, with a virtual steering wheel being controlled just by the position of the user's hands in the air. In another embodiment, the disclosed system and method may include simulating operation of the actual vehicle utilizing virtual controls, where the user may sit in the car seat and feel the actual interior of the vehicle around the user, with the inputs of the simulation being provided by virtual controls presented graphically to the user.

The disclosed system and method may be capable of operating a virtual reality simulator. The disclosed system and method may be capable of operating an augmented reality simulator. The disclosed system and method may be capable of operating either a virtual reality simulator or an augmented reality simulator. The disclosed system and method may be capable of operating a mixture of virtual and augmented reality programming, where a user may be able to select how much of the graphic rendering of the headset is virtual and how much is augmented. In one example, the controls of the actual vehicle to be utilized by the user may be captured in images and graphically presented to the user as augmented reality features, while a remainder of a view of the user may be virtual.

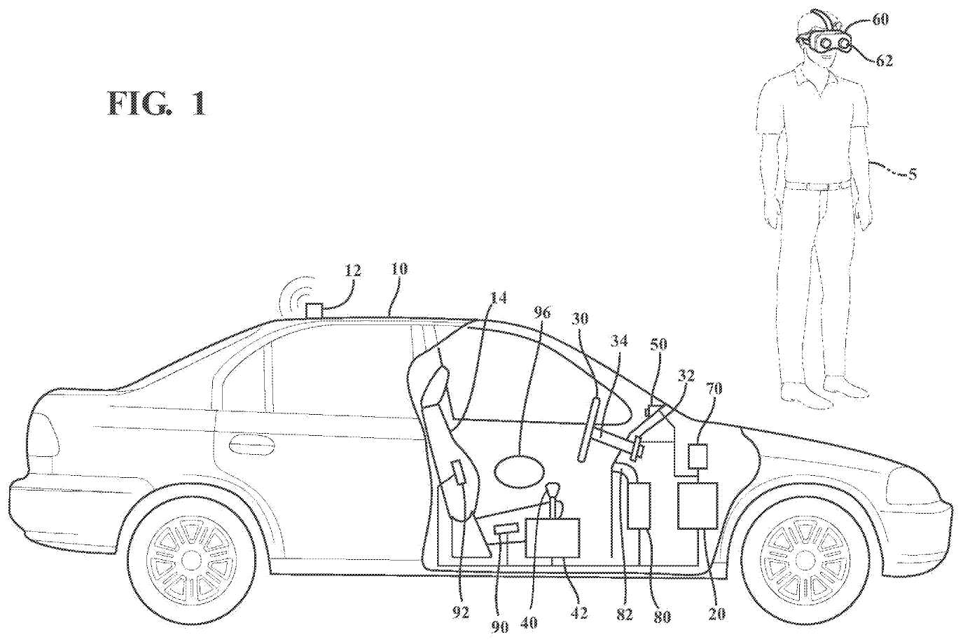

Referring now to the drawings, wherein like reference numbers refer to like features throughout the several views, FIG. 1 schematically illustrates a vehicle 10 configured for operating a computerized augmented-virtual reality driving simulator. The vehicle 10 is an actual vehicle and is illustrated including a computerized simulation controller 20 including programming operable to control operation of the simulation and additionally to control activation of a simulation mode upon the actual controls of the vehicle, disconnecting the actual controls from operation of the actual vehicle. A user 5 is additionally illustrated wearing a headset 60. The headset 60 includes a camera device 62 useful for operating augmented reality and for tracking movement of a head and hands of the user 5. The headset 60 may include a virtual reality headset such as the Meta® Quest 2® headset sold by the Facebook Technologies, LLC company of Irvine, California, or a similar device. The user 5 is illustrated standing outside of the vehicle 10 for purposes of illustration. During operation of the simulation, the user 5 may be seated upon a seat 14 of the vehicle 10. The vehicle 10 is further illustrated including a steering wheel 30, a transmission gear selector 40, a wireless short-range communication device 70, a climate control system 80, and a wireless long-range communication device 12.

The exemplary steering wheel 30 is attached to a steering column 34 and a steering wheel mode selection device 32. The steering wheel mode selection device 32 includes mechanical and/or electronic mechanisms useful for selectively connecting and disconnecting the steering wheel 30 to a steering system of the vehicle 10 configured to turn actual wheels of the vehicle 10 left and right. Based upon control signals provided by the computerized simulation controller 20, the steering wheel 30 may be selectively disconnected from the steering system of the vehicle 10, and an actual rotation of the steering wheel 30 may be utilized as a control input to a simulation operated by the computerized simulation controller 20. The steering wheel 30, the steering column 34, and/or the steering wheel mode selection device 32 may additionally include a telescoping feature. During normal operation of the vehicle 10, the user 5 may utilize the telescoping feature to position the steering wheel 30 a comfortable distance from the user 5. In a simulation mode, the telescoping feature may be utilized as an additional input to the computerized simulation controller. Additionally, the steering wheel 30, the steering column 34, and/or the steering wheel mode selection device 32 may include servo motors or other features useful to make the steering wheel 30 vibrate, pulse in a direction, or otherwise provide haptic feedback to the user 5 during operation of a simulation.

The transmission gear selector 40 includes a transmission gear selector mode selection device 42. The transmission gear selector mode selection device 42 includes mechanical and/or electronic mechanisms useful for selectively connecting and disconnecting the transmission gear selector 40 to a transmission system of the vehicle 10 configured to select a mode of travel of the vehicle 10. Based upon control signals provided by the computerized simulation controller 20, the transmission gear selector 40 may be selectively disconnected from the transmission system of the vehicle 10, and an actual position of the transmission gear selector 40 may be utilized as a control input to a simulation operated by the computerized simulation controller 20.

The wireless short-range communication device 70 is useful to provide communication between the computerized simulation controller 20 and the headset 60. The wireless short-range communication device 70 is further useful to provide communication between the computerized simulation controller 20 and a computerized cellular device of the user 5 such as a smartphone. The wireless short-range communication device 70 may include Wi-fi communications and/or Bluetooth® communications. In one embodiment, the wireless short-range communication device 70 may be substituted with a data cable connecting the headset 60 to the vehicle 10, eliminating the usefulness of wireless communication between the vehicle 10 and the headset 60.

The climate control system 80 may include a blower unit configured to create a flow of air through air ducts 82. The climate control system 80 may further include a heater core configured to heat the flow of air and an evaporator core configured to cool and remove humidity from the flow of air. The climate control system 80 may be controlled by the computerized simulation controller 20 during operation of a simulation to provide a sensation of a flow of air to user 5 based upon contextual operation of the simulation.

The wireless long-range communication device 12 may include cellular communications and may provide an ability for the computerized simulation controller 20 to update, download content, and interact with other users in other vehicles remotely.

The vehicle 10 is further illustrated including an interior camera device 50 useful to capture images of the user 5 and interior features of the vehicle 10. The interior camera device 50 is optional and may be used to replace or augment data collected from the camera device 62. A plurality of camera devices 50 may be present within the vehicle 10 and may capture different perspectives within the vehicle 10. The vehicle 10 is further illustrated including a speaker 96 of an audio system of the vehicle, wherein the speaker 96 may be utilized to emit audio content of the simulation to the user 5. The headset 60 may additionally or alternatively include audio headphone outputs to the user 5. The vehicle 10 is further illustrated including the seat 14 which may be equipped with vibration unit 90 in a base of the seat 14 and vibration unit 92 in a back of the seat 14. The seat 14 may further include electronic height, tilt, recline angle, and lumbar control features which may be controllable by the computerized simulation controller 20.

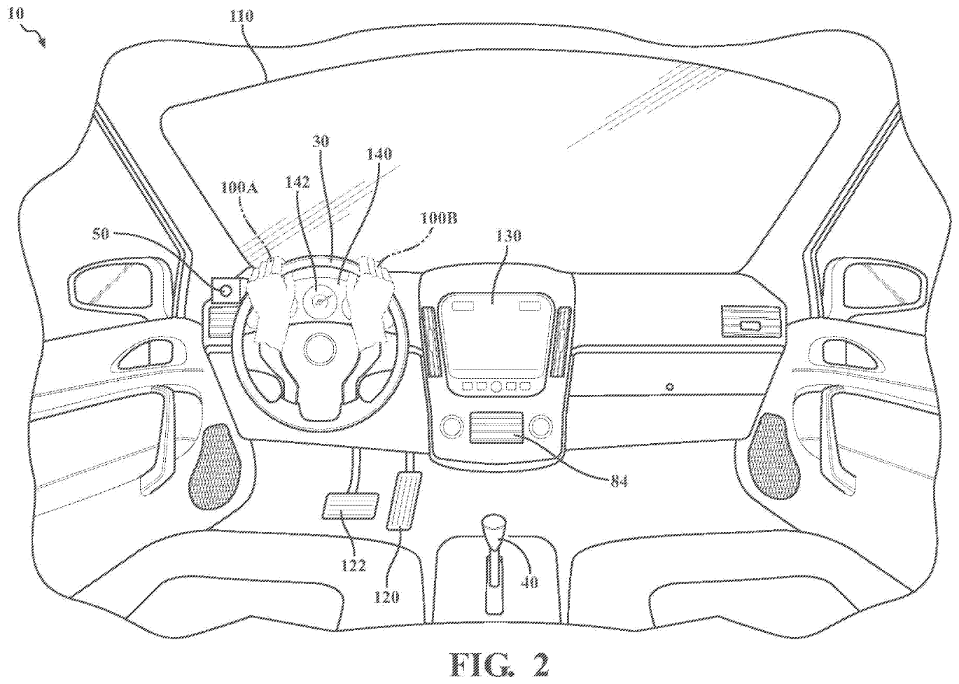

FIG. 2 schematically illustrates an interior of the vehicle 10 of FIG. 1. FIG. 2 illustrates actual control features that are present within the vehicle 10 that may be utilized to provide control inputs to the computerized simulation controller 20. A windscreen 110 is illustrated. The steering wheel 30 is illustrated, including exemplary hands 100A and 100B of the user upon the steering wheel 30. The interior camera device 50, the transmission gear selector 40, an accelerator pedal 120, and a brake pedal 122 are illustrated. A climate control output vent 84 is illustrated which is connected to the air ducts 82 of FIG. 1. An instrument panel 140 including a speedometer 142 is illustrated. Outputs of the instrument panel 140 may be disabled during the simulation, for example, during a virtual reality simulation, where the user 5 of FIG. 1 does not view a representation of the actual interior of the vehicle 10. Outputs of the instrument panel 140 may be controlled as an output of the simulation, for example, during an augmented reality simulation, where images of the instrument panel 140 including an output of the speedometer 142 may be incorporated into the graphics rendered to the user 5. A touchscreen input/output display 130 is illustrated. The touchscreen input/output display 130 may be utilized to provide inputs to the computerized simulation controller 20. The touchscreen input/output display may be utilized to provide outputs from the computerized simulation controller 20. In one embodiment, the touchscreen input/output display 130 may provide a simplified rendering of what the user 5 is seeing through the headset 60 so that other persons in the vehicle 10 may follow along with the simulation.

The accelerator pedal 120 and the brake pedal 122 may each include mechanical and/or electronic mechanisms useful for selectively connecting and disconnecting the accelerator pedal 120 and the brake pedal 122 to a propulsion system and a braking system, respectively, of the vehicle 10 configured to control an actual speed of the vehicle. Based upon control signals provided by the computerized simulation controller 20, the accelerator pedal 120 and the brake pedal 122 may each be selectively disconnected from the systems of the vehicle 10, and an actual depression of each of the accelerator pedal 120 and the brake pedal 122 may be utilized as control inputs to a simulation operated by the computerized simulation controller 20.

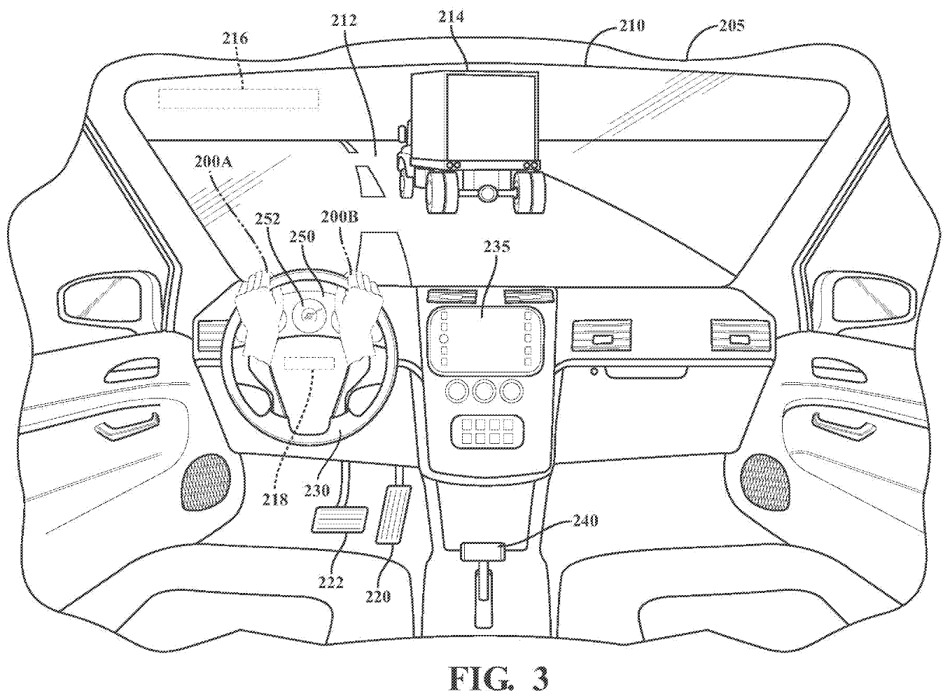

FIG. 3 illustrates a graphical rendering 205 of a simulation operated by the computerized simulation controller 20 of FIG. 1 within the headset 60 of FIG. 1. The graphical rendering 205 includes a representation of a windscreen 210, a representation of a steering wheel 230, a representation of a touchscreen display 235, a representation of an instrument panel 250, a representation of a transmission gear selector 240, a representation of an accelerator pedal 220, and a representation of a brake pedal 222. If the simulation being operated is a virtual reality simulation, then each of the representations 210, 220, 222, 230, 235, 240, and 250 may be unrelated to actual features of the vehicle 10 of FIG. 1 in which the user 5 may be seated. If the simulation being operated is an augmented reality simulation, then each or some of the representations 210, 220, 222, 230, 235, 240, and 250 may be images of the interior of the vehicle 10 in which the user 5 is seated and may additionally include computer generated graphic renderings intermixed with the images of the interior of the vehicle 10. Virtual hand positions 200A and 200B may be rendered based upon image data providing actual locations of the hands of the user 5.

Details or outputs of the simulation being operated by the computerized simulation controller 20 may be displayed within the context of the representation of the windshield 210. A graphical representation of a road surface 212 is illustrated. A graphical representation of another vehicle 214 is additionally illustrated.

Text, emojis, status bars, or other information may be provided within the context of the graphical rendering 205. An exemplary text box 216 is provided within the representation of the windshield 210, which may provide a current lap time in a simulated race or may provide a feature of the vehicle being virtually test driven. An exemplary text box 218 rendered upon the steering wheel 230 may provide an identity of a vehicle being virtually test driven or may include a limited-edition version of the steering wheel 230, for example, awarded for having a fastest lap time in a previous race. The representation of the touchscreen display 235 may provide an interactive list of information, for example, with a hand motion detected by the user 5 to the representation of the touchscreen display 235 being used to select or change information provided to the user 5. The representation of the instrument panel 250 may include a virtual speedometer 252 providing an output of the computerized simulation controller 20, describing a speed of the vehicle being simulated. The details of the graphical rendering 205 are exemplary, and the disclosure is not intended to be limited to the particular examples provided herein. Features, graphics, vehicle models, and other portions of the graphical rendering may include limited-edition NFT items, where ownership of the NFT items may be established through blockchain methods.

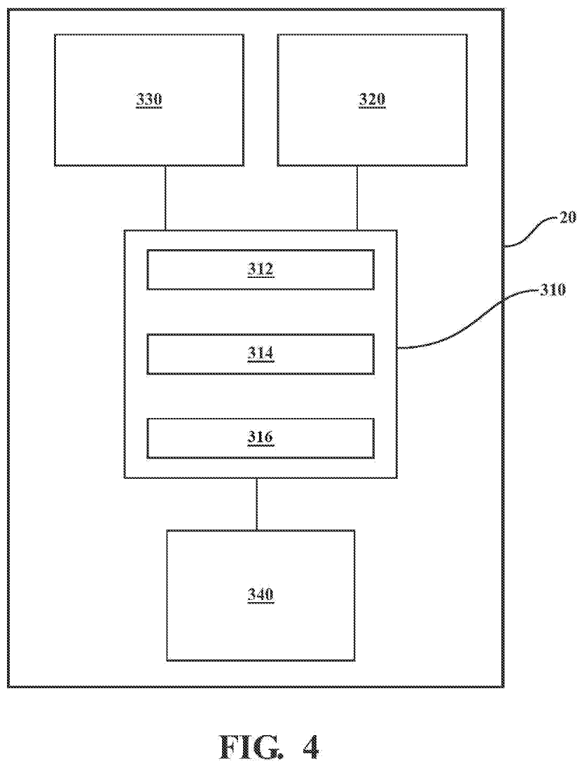

FIG. 4 schematically illustrates the computerized simulation controller 20 of FIG. 1. The computerized simulation controller 20 includes a computerized processing device 310, a communications device 320, an input output coordination device 330, and a memory storage device 340. It is noted that the computerized simulation controller 20 may include other components and some of the components are not present in some embodiments.

The processing device 310 may include memory, e.g., read only memory (ROM) and random-access memory (RAM), storing processor-executable instructions and one or more processors that execute the processor-executable instructions. In embodiments where the processing device 310 includes two or more processors, the processors may operate in a parallel or distributed manner. The processing device 310 may execute the operating system of the computerized simulation controller 20. Processing device 310 may include one or more modules executing programmed code or computerized processes or methods including executable steps. Illustrated modules may include a single physical device or functionality spanning multiple physical devices. In the illustrative embodiment, the processing device 310 also includes a simulation mode authorization and management module 312, a simulation operation module 314, and a virtual/augmented reality rendering module 316, which are described in greater detail below.

The communications device 320 may include a communications/data connection with a bus device configured to transfer data to different components of the system and may include one or more wireless transceivers for performing wireless communication.

The input output coordination device 330 includes hardware and/or software configured to enable the processing device 310 to receive and/or exchange data with on-board sensors of the host vehicle and to provide control of switches, modules, and processes throughout the vehicle based upon determinations made within the processing device 310.

The memory storage device 340 is a device that stores data generated or received by the computerized simulation controller 20. The memory storage device 340 may include, but is not limited to, a hard disc drive, an optical disc drive, and/or a flash memory drive.

The vehicle 10 of FIG. 1 may be operated in an actual operation mode and a simulation mode. The simulation mode authorization and management module 312 may include programming to monitor prerequisite conditions to permit a change from a first of the modes to a second of the modes. For example, the simulation mode authorization and management module 312 may include programming to monitor and determine that the vehicle 10 of FIG. 1 is actually in park mode prior to enabling a transition from the actual operation mode to the simulation mode. In one embodiment, entry into the simulation mode may require that a key of the vehicle 10 be removed from the ignition. The simulation mode authorization and management module 312 may include programming to retain the vehicle 10 in the park mode until some action occurs, for example, a key is turned in the ignition of the vehicle 10. In another example, the simulation mode authorization and management module 312 may require verbal confirmation from the user 5 of FIG. 1 that the simulation mode is to cease and that the actual operation mode is to be activated. The simulation mode authorization and management module 312 may further include programming to control the steering wheel mode selection device 32 and the transmission gear selector mode selection device 42, controlling selective connection and disconnection of the actual control features from the actual systems of the vehicle. The simulation mode authorization and management module 312 may determine an identity of user 5, for example, by analysis of images from the interior camera device 50, and may prevent activation of the actual operation mode if the user 5 is not an authorized user of the vehicle, for example, a person without a driver's license or an underage user.

The simulation operation module 314 may include programming to operate the desired simulation within the vehicle 10. For example, the simulation operation module 314 may include a program configured for operating a race, a program configured for operating a test drive, a program configured for training a student driver, a program configured to simulate operation of a boat, or a program to simulate operation of an airplane. The simulation operation module 314 may include programming to monitor inputs to actual vehicle controls and/or to virtual controls graphically rendered to the user 5. The simulation operation module 314 may include programming to monitor images of hand gestures of the user 5 and determine desired commands in the simulation corresponding to the hand gestures. The simulation operation module 314 may include rules of operation of the simulation, for example, monitoring simulated operation of the virtual vehicle upon the roadway, determining whether the virtual vehicle is maintaining position within a lane, and generating an output based upon the determination. The simulation operation module 314 may determine a location of the virtual vehicle relative to other virtual vehicles, for example, applying rules that prevent both virtual vehicles from occupying a same virtual location. The simulation operation module 314 may include rules related to operating a race, for example, monitoring a ranking of one virtual vehicle versus a second vertical vehicle. The simulation operation module 314 may include operations related to providing a virtual test drive, for example, monitoring an audio system input to a microphone device, determining whether the user 5 is asking a question about the virtual vehicle, and referencing a look-up table to provide an answer to the question. The simulation operation module 314 may include rules related to training a student driver, for example, monitoring compliance with basic driving rules such as coming to a complete stop at a stop sign. The simulation operation module 314 may provide playback of a training simulation after it is complete along with annotated critiques of the simulated driving. The simulation operation module 314 may include rules related to operating a boat, for example, providing a reaction when the virtual boat crosses another virtual boat's wake or when the virtual boat turns too fast at high speed. The simulation operation module 314 may include rules related to operating a plane, for example, providing a reaction when the virtual airplane goes below a stall speed or changing operation of the virtual airplane when flaps are extended. The simulation operation module 314 may include programming to simulate a virtual environment including other virtual vehicles, virtual pedestrians, virtual weather, virtual time of day, and other simulated details. The simulation operation module 314 may include programming to control vehicle systems, such as vibration, haptic, climate control, and audio outputs of the vehicle 10, based upon operation of the simulation. The simulation operation module 314 may provide for social interaction of the user 5 with other users through the wireless long-range communication device 12. The simulation operation module 314 may include programming to operate 360-degree sound, such that passing another virtual vehicle within the simulation results in directional sound from the sound system of vehicle 10 approximating the actual sounds and direction of passing another vehicle in the real world. The simulation operation module 314 may include a variety of rules, simulated environmental details, simulated vehicles, simulated driving or operating conditions, simulated race or game contexts, social applications, and other relevant programming to a simulation, and the disclosure is not intended to be limited to the examples provided herein.

The headset 60 of FIG. 1 may include programming to monitor computerized inputs and render graphics related to a particular virtual or augmented environment. The virtual/augmented reality rendering module 316 may include programming to facilitate translation of simulation details determined or provided as outputs from the simulation operation module 314 to the headset 60. The virtual/augmented reality rendering module 316 may operate a three-dimensional computer model of the simulated environment. The virtual/augmented reality rendering module 316 may include programming to manage and provide an output related to a perspective of the user 5 wearing the headset 60 relative to the simulated environment. The virtual/augmented reality rendering module 316 may provide data in a particular format useful to the headset 60 to enable programming of the headset 60 to render the desired graphics. The virtual/augmented reality rendering module 316 may communicate with the headset 60 to determine a brand of the headset 60, a model number of the headset 60, a software or firmware version operated by the headset 60, or other information to make outputs of the simulation operation module 314 compatible with the headset 60.

The computerized simulation controller 20 is provided as an exemplary computerized device capable of executing programmed code to operate the disclosed method. In one exemplary embodiment, some of the functionality described in relation to the computerized simulation controller 20 may instead be operated by the headset 60. A number of different embodiments of the computerized simulation controller 20 and modules operable therein are envisioned, and the disclosure is not intended to be limited to examples provided herein.

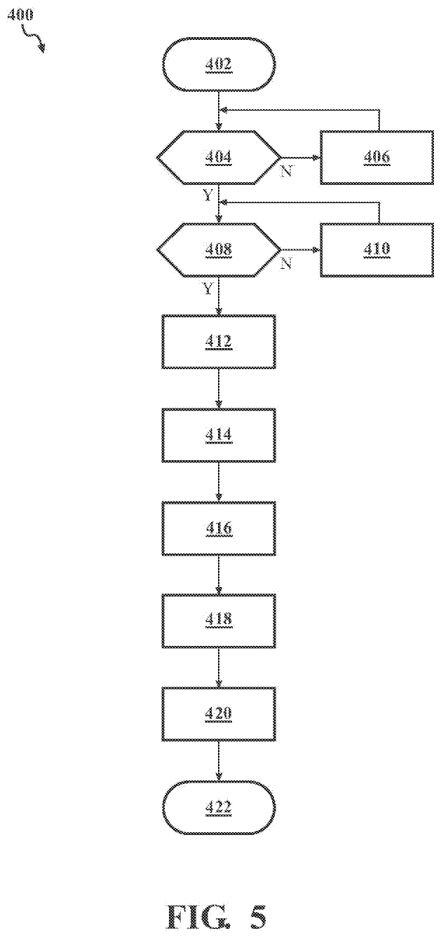

FIG. 5 is a flowchart illustrating a method 400 to operate a simulation in the vehicle 10 of FIG. 1. The method 400 is described in relation to the vehicle 10 and user 5 of FIG. 1. The method 400 may be operated in combination with other embodiments of vehicles, and the disclosure is not intended to be limited to the examples provided herein. The method 400 starts at step 402. At step 404, the user 5 provides an input indicating a desire to activate a simulation mode in the vehicle 10. At step 406, a determination is made whether the vehicle 10 is in a park mode. If the vehicle 10 is not in a park mode, the method 400 advances to step 408, where the user 5 is informed that the simulation mode is available when the vehicle 10 is in park mode, and the method 400 returns to step 406. If the vehicle is in park mode, the method 400 advances to step 410, wherein a determination is made whether the vehicle 10 is in communication with the headset 60. If the vehicle 10 is not in communication with the headset 60, the method 400 advances to step 412, where the user is prompted to electronically connect the headset 60 to the vehicle 10, and the method 400 returns to the step 410. If the vehicle 10 is in communication with the headset 60, the method 400 advances to step 414. At the step 414, operation of the headset 60 and the interior camera device 50 are activated to collect camera data useful to track hands 100A, 100B and a position of the steering wheel 30. At step 416, the user 5 is prompted to calibrate operation of the steering wheel 30 to desired simulation inputs. At step 418, operation of the accelerator pedal 120 and the brake pedal 122 are activated to collect data useful to provide inputs to the simulation. At step 420, the computerized simulation controller 20 operates the simulation and provides data to the headset 60, and the headset 60 and the vehicle 10 provide coordinated outputs to the user 5 to simulate operation of the vehicle, boat, or airplane according to the simulation being operated. The method 400 ends at step 422. The method 400 is provided as an example for operation of the vehicle 10 and headset 60, a number of additional or alternative method steps are envisioned, and the disclosure is not intended to be limited to the examples provided herein.

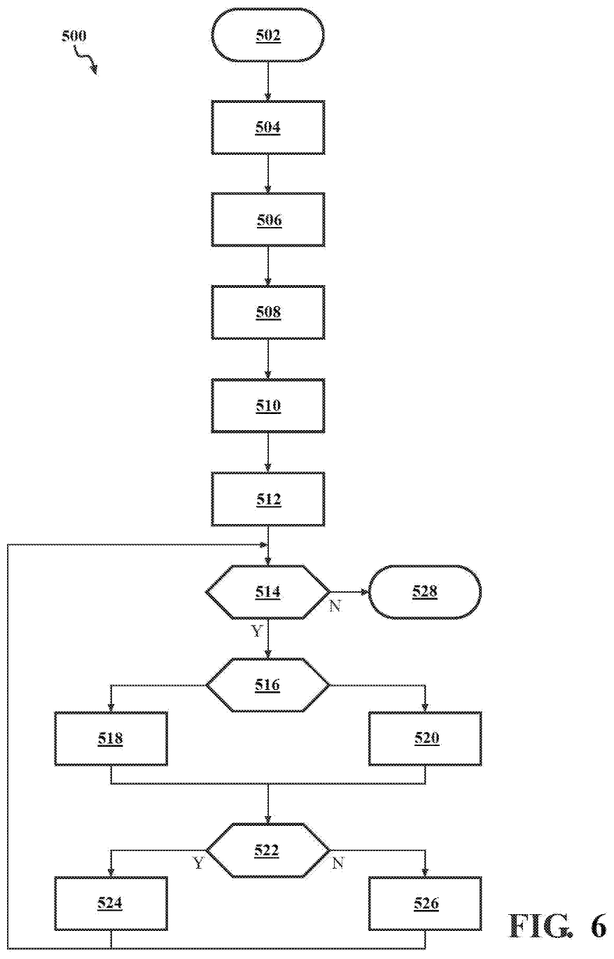

FIG. 6 is a flowchart illustrating a method 500 for managing features of a simulation operated in the vehicle 10 of FIG. 1. The method 500 is described in relation to the vehicle 10 and user 5 of FIG. 1. The method 500 may be operated in combination with other embodiments of vehicles, and the disclosure is not intended to be limited to the examples provided herein. The method 500 starts at step 502. At step 504, accelerator pedal position, brake pedal position, and location data of hands of the user 5 are sent to the headset 60. At step 506, in advance of operating the simulation, options to the simulation are presented to the user 5. The options may be provided as graphics within the headset 60. In another embodiment, the options may be provided through the vehicle audio system. Options presented to the user 5 may be alternatively highlighted or cycled through by turning the steering wheel. Options presented to the user 5 may be selected by depression of the accelerator pedal 120. A cancel or go back feature in the options may be operated by depression of the brake pedal 122. At step 508, the user is prompted to select a vehicle to simulate from a list of available virtual vehicles. At step 510, the user is prompted to select a simulated map on which to operate the simulation. At step 512, the simulation is activated, with graphics, vibration outputs, haptic outputs, climate control system outputs, and audio outputs being activated to provide an excellent and immersive experience. At step 514, a determination is made whether the simulation remains active. If the simulation does not remain active, the method 500 advances to step 528, where the simulation ends. If the simulation does remain active, the method 500 advances to step 516, wherein a determination is made whether the accelerator pedal 120 or the brake pedal 122 is presently being depressed. If the accelerator pedal 120 is presently being depressed, the method 500 advances to step 518, where a degree of depression of the accelerator pedal 120 is used to determine a change in speed of the virtual vehicle being simulated. If the accelerator pedal 120 is pressed a little, the speed of the virtual vehicle may decrease or stay constant. If the accelerator pedal 120 is significantly depressed or fully depressed, the speed of the virtual vehicle may increase or increase sharply. If the brake pedal 122 is presently being depressed, the method 500 advances to step 520, where a speed of the virtual vehicle is reduced or maintained at zero, with a rate of slowing the virtual vehicle being controlled based upon a degree of depression of the brake pedal 122. After operation of the step 518 or the step 520, the method 500 advances to the step 522, where a determination is made whether the virtual vehicle is presently being driven upon a bumpy road. If the virtual vehicle is presently being driven on a bumpy road, the method 500 advances to step 524, where the vibration unit 90 and/or the vibration unit 92 may be activated and the graphical display of the headset 60 may simulate vibration to simulate a bumpy ride corresponding to the bumpy road. If the virtual vehicle is not presently being driven on a bumpy road, the method 500 advances to the step 526, wherein the graphical display includes a smooth image and an audio output of the audio system of vehicle 10 may be controlled to provide a smooth tone corresponding to driving on a smooth surface. After operation of the step 524 or the step 526, the method 500 returns to the step 514. The method 500 is provided as an example for operation of the vehicle 10 and headset 60, a number of additional or alternative method steps are envisioned, and the disclosure is not intended to be limited to the examples provided herein.

While the best modes for carrying out the disclosure have been described in detail, those familiar with the art to which this disclosure relates will recognize various alternative designs and embodiments for practicing the disclosure within the scope of the appended claims.

What is claimed is:

1. A system for an augmented-virtual reality simulator using a vehicle, the system comprising:
the vehicle including:
a control feature configured for selective use in an actual operation mode, wherein the control feature is utilized to control actual operation of the vehicle, and in a simulation mode, wherein the control feature is utilized as an input device to the augmented-virtual reality simulator;
a computerized simulation controller including programming to:
monitor activation of the augmented-virtual reality simulator;
command activation of the simulation mode based upon the activation of the augmented-virtual reality simulator;
monitor inputs to the control feature; and
operate the augmented-virtual reality simulator based upon the inputs to the control feature; and
a headset configured for being worn by a user providing a graphical rendering to the user based upon the augmented-virtual reality simulator.

2. The system of claim 1, wherein the control feature includes one of a steering wheel, an accelerator pedal, a brake pedal, or a transmission gear selector.

3. The system of claim 1, wherein the vehicle includes a plurality of control features configured for selective use in an actual operation mode, wherein the control features are utilized to control actual operation of the vehicle, and in a simulation mode, wherein the control features are utilized as input devices to the augmented-virtual reality simulator; and
wherein the plurality of control features include a steering wheel, an accelerator pedal, a brake pedal, and a transmission gear selector.

4. The system of claim 1, wherein the computerized simulation controller further includes programming to:
monitor a transmission mode of the vehicle;
enable activation of the augmented-virtual reality simulator based upon the transmission mode indicating that the vehicle is in park.

5. The system of claim 1, wherein the augmented-virtual reality simulator includes virtual reality, wherein the graphical rendering replaces visible features in an environment of the user.

6. The system of claim 1, wherein the augmented-virtual reality simulator includes augmented reality, wherein the graphical rendering includes a mixture of images of visible features in an operating environment of the user and computerized graphics rendered based upon a three-dimensional model.

7. The system of claim 1, wherein the augmented-virtual reality simulator includes a driving simulation.

8. The system of claim 7, wherein the driving simulation includes a race.

9. The system of claim 7, wherein the driving simulation includes a virtual test drive.

10. The system of claim 7, wherein the driving simulation includes driving instruction for a student driver.

11. The system of claim 1, wherein the augmented-virtual reality simulator includes a simulation of operating a boat or an airplane.

12. The system of claim 1, wherein the augmented-virtual reality simulator includes operation of one of vibration outputs, haptic outputs, climate control system outputs, or audio outputs.

13. The system of claim 1, wherein the augmented-virtual reality simulator includes limited-edition non-fungible tokens.

14. A system for an augmented-virtual reality simulator using a vehicle, the system comprising:
the vehicle including:
a control feature configured for selective use in an actual operation mode, wherein the control feature is utilized to control actual operation of the vehicle, and in a simulation mode, wherein the control feature is utilized as an input device to the augmented-virtual reality simulator;
a computerized simulation controller including programming to:
monitor activation of the augmented-virtual reality simulator;
command activation of the simulation mode based upon the activation of the augmented-virtual reality simulator;
monitor inputs to the control feature; and
operate the augmented-virtual reality simulator including a driving simulator configured to simulate a virtual test drive based upon the inputs to the control feature; and
a headset configured for being worn by a user providing a graphical rendering to the user based upon the augmented-virtual reality simulator; and
wherein the augmented-virtual reality simulator enables the user to select from a plurality of virtual vehicles.

15. The system of claim 14, wherein the augmented-virtual reality simulator enables the user to select from a plurality of maps upon which to operate the virtual test drive.

16. The system of claim 14, wherein the augmented-virtual reality simulator:
identifies a bumpy road condition; and
controls a vibration unit in a seat of the user based upon the bumpy road condition.

17. A method for an augmented-virtual reality simulator using a vehicle, the method comprising:
operating the vehicle including a control feature configured for selective use in an actual operation mode, wherein the control feature is utilized to control actual operation of the vehicle, and in a simulation mode, wherein the control feature is utilized as an input device to the augmented-virtual reality simulator;
within a computerized processor:
monitoring activation of the augmented-virtual reality simulator;
commanding activation of the simulation mode based upon the activation of the augmented-virtual reality simulator;
monitoring inputs to the control feature; and
operating the augmented-virtual reality simulator based upon the inputs to the control feature; and
within a headset configured for being worn by a user, providing a graphical rendering to the user based upon the augmented-virtual reality simulator.

18. The method of claim 17, wherein monitoring inputs to the control feature includes monitoring inputs to a steering wheel.

19. The method of claim 17, further comprising, within the computerized processor, monitoring a transmission mode of the vehicle; and
enabling activation of the augmented-virtual reality simulator based upon the transmission mode indicating that the vehicle is in park.
